(19) United States
(12) Patent Application Publication
(10) Pub. No.: US 2012/0006405 A1
(43) Pub. Date: Jan. 12, 2012

(54) PANEL-MOUNTED PHOTOVOLTAIC SYSTEM WITH FRESNEL REFLECTOR

(75) Inventor: Brian M. Sutin, Claremont, CA (US)

(73) Assignee: HAMILTON SUNDSTRAND CORPORATION, Windsor Locks, CT (US)

(21) Appl. No.: 12/831,659

(22) Filed: Jul. 7, 2010

(51) Int. Cl. H01L 31/0232

(52) U.S. Cl. 136/259

(57) ABSTRACT

A system comprises first and second Fresnel reflectors. Each of the Fresnel reflectors comprises a Fresnel surface with a focus, a radiating surface opposite the Fresnel surface, and a photovoltaic element mounted to the Fresnel surface, in thermally conducting contact with the radiating surface. The first and second Fresnel reflectors form a vertex having a dihedral angle, such that the focus of the first Fresnel reflector is directed toward the photovoltaic element on the second Fresnel reflector, and such that the focus of the second Fresnel reflector is directed toward the photovoltaic element on the first Fresnel reflector.

### BACKGROUND

This invention relates generally to solar energy, and specifically to solar concentrators. In particular, the invention concerns a Fresnel-type solar concentrator suitable for photovoltaic power generation.

Concentrated solar power (CSP) systems utilize solar concentrators to focus sunlight from a relatively large collection area down to a smaller focus area, increasing flux, temperature and conversion efficiency. Both lenses and mirrors are used for focusing, but reflector-type concentrators are often employed on larger-scale systems in order to lower transmission losses and reduce overall weight and cost.

Reflector geometry varies based on the type of technology employed, and the desired level of solar concentration. Relatively low-temperature rooftop heating systems, for example, typically employ flat or linear geometries and track along a single axis, or may not track at all. Higher-concentration systems including steam and turbine-based electrical generators utilize linear-parabolic optical geometry or “power tower” designs, some of which employ highly coordinated two-axis tracking systems to focus large heliostat arrays onto a central receiver.

Concentrating photovoltaic (CPV) systems utilize a photovoltaic (PV) cell or similar element for converting sunlight directly into electrical power via photovoltaic action. As used herein, PV elements also encompass photoelectric devices, in which electrical power is generated by direct photoelectric emission, and thermionic devices, in which electrons are emitted from a hot cathode surface, generating current across a potential barrier with respect to the (cooler) anode.

CPV systems incorporate a range of linear, parabolic, parabolic trough and other reflector geometries. Design issues include collection efficiency, shadowing and other losses. In addition, target heating should be controlled in order to reduce resistance and prevent damage to the PV elements. These issues raise particular challenges for space-based applications, where design simplicity, size envelope and mass considerations are at a premium.

### SUMMARY

This invention concerns a concentrating photovoltaic power system. The system includes a plurality of Fresnel reflectors, each comprising a Fresnel surface with a focus, a radiating surface opposite the Fresnel surface, and a photovoltaic element. The photovoltaic element is mounted to the Fresnel surface, in thermally conducting contact with the radiating surface. Two of the Fresnel reflectors are coupled to form a vertex having a dihedral angle, and the planes are oriented such that the focus of each Fresnel reflector is directed toward a photovoltaic element mounted to a different Fresnel reflector.

### BRIEF DESCRIPTION OF THE DRAWINGS

FIG. 1 is a cross-sectional schematic of a concentrating photovoltaic power system with two Fresnel reflectors.

FIG. 2 is an illustration of facet geometry for a Fresnel reflector with a panel-mounted photovoltaic element.

FIG. 3 is an illustration of focusing geometry for a linear-parabolic Fresnel reflector.

FIG. 4 is a cross-sectional schematic of a two-panel concentrating photovoltaic power system, showing the dihedral angle.

FIG. 5 is a perspective view of a concentrating photovoltaic power system, in a conic dish embodiment.

FIG. 6A is a perspective view of a concentrating photovoltaic power system, in a two-panel linear parabolic embodiment.

FIG. 6B is a perspective view of an array of two-panel linear-parabolic concentrating photovoltaic systems.

FIG. 7A is a perspective view of a concentrating photovoltaic power system, in a four-panel bilinear parabolic embodiment.

FIG. 7B is a perspective view of an array of four-panel bilinear parabolic concentrating photovoltaic power systems.

FIG. 8A is a perspective view of a concentrating photovoltaic power system with two-dimensional focusing.

FIG. 8B is a perspective view of an array of concentrating photovoltaic power systems with two-dimensional focusing.

### DETAILED DESCRIPTION

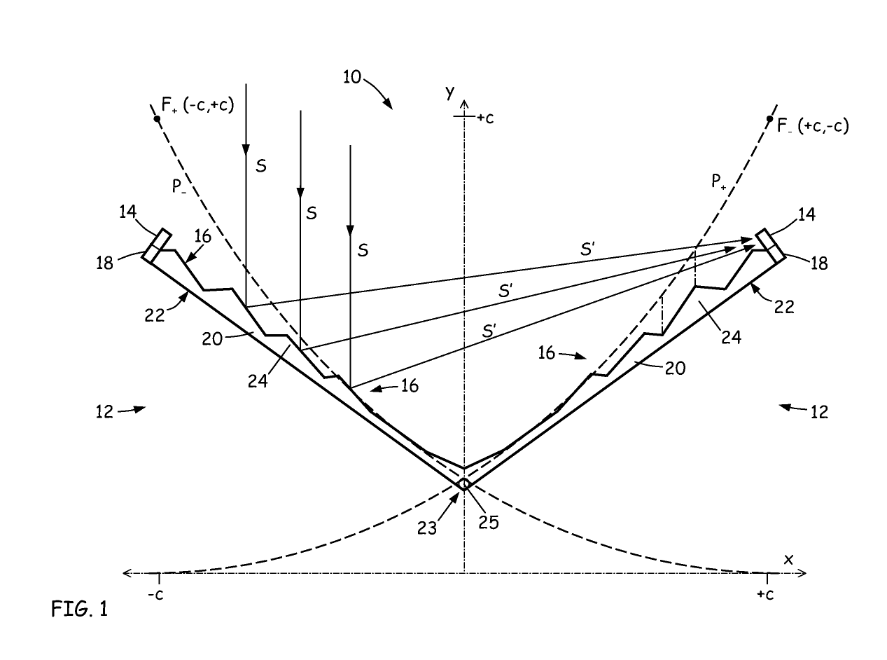

FIG. 1 is a cross-sectional view of concentrating photovoltaic (CPV) system 10. In this embodiment CPV system 10 comprise two Fresnel reflectors 12 with photovoltaic (PV) elements 14 and reflecting Fresnel surfaces 16. PV elements 14 are mounted to Fresnel surfaces 16 via panel mounts 18, forming a direct thermally conductive coupling to minor backer panels 20 and radiating surfaces 22.

Fresnel surfaces 16 comprise facets 24 formed on the front (first) surface of minor backer panels 20, with radiating surfaces 22 on the back (second surface), opposite Fresnel surfaces 16. Facets 24 are individually angled with respect to Fresnel reflectors 12 in order to focus light from source (incident light) direction S toward PV elements 14, along focus direction S′. Heat from PV elements 14 is conducted directly to mirror backers 20 via panel mounts 18, and dissipated by infrared (IR) emission from radiating surfaces 22.

PV elements 14 comprise solar cells or similar devices for converting light into electrical energy. In semiconductor-based photovoltaic embodiments, suitable PV elements 14 include, but are not limited to, monocrystalline silicon, polycrystalline silicon, amorphous silicon, cadmium telluride, gallium telluride, copper indium selenide, copper indium sulfide, and germanium-based solid state devices, with varying sensitivity and photovoltaic efficiency across the IR, visible and ultraviolet (UV) ranges. Alternatively, PV elements 14 comprise photoelectric or thermionic devices, as described above, or a transparent conducting film (TCF), transparent conducting oxide (TCO), transparent conducting polymer (TCP), or carbon nanotube or nano-antenna based device. In some of these embodiments PV elements 14 have relatively higher or lower sensitivity and efficiency as a function of wavelength, particularly in the IR and UV.

Fresnel reflectors 12 are oriented in a V-shaped configuration to form vertex 23, for example by coupling or joining mirror backers 20 at hinge mechanism 25. This allows Fresnel reflectors 12 to fold flat for storage and transportation and then unfold during deployment, for example in a space environment. In other embodiments, Fresnel reflectors 12 utilize a stacking/unstacking or fan-type deployment system to form vertex 23, or a permanent rigid mount for ground installation.

In the particular embodiment of FIG. 1, panel mounts 18 are positioned in edge locations on Fresnel reflectors 12, with panel mounts 18 located opposite vertex 23. When Fresnel reflectors 12 are deployed, PV elements 14 are spaced in a lateral direction along horizontal axis x. The sun (or other radiation source) is oriented along vertical axis y, with radiation incident along source direction S, along or anti-parallel to vertical axis y.

As shown in FIG. 1, CPV system 10 has a two-panel linear parabolic focusing geometry. In this configuration Fresnel surface 16 on left-hand reflector 12 focuses light from source direction S onto right-hand PV element 14, and Fresnel surface 16 on right-hand reflector 12 focuses light onto left-hand PV element 14. In contrast to traditional parabolic reflector designs, however, Fresnel surfaces 16 are formed as a set of facets 24 on Fresnel reflectors 12, combining the optical advantages of parabolic focusing with the structural advantages of a substantially planar or linear concentrator design.

More specifically, parabolic sections P₊ and P₋ are represented by the formula:

$${f}_{\pm } ( x ) = \frac{{( c \pm x )}^{2}}{4 c} , \qquad [ 1 ]$$

with functional values on the y axis (the range) and input values on the x axis (the domain). Right-hand parabolic surface P₊ (positive sign in Eq. 1) has focus F₊ at (−c,+c), on left-hand parabolic section P₋, and left-hand parabolic surface P₋ (negative sign in Eq. 1) has focus F₋ at (+c,+c), on right-hand parabolic section P₊.

Fresnel surfaces 16 are constructed by dividing parabolic surfaces P_{±} into a number of sections and translating to Fresnel reflectors 12, forming Fresnel surfaces 16 on the front surfaces of mirror backers 20 in the form of facets 24. Depending on embodiment, individual facets 24 sometimes retain the particular curved (nonlinear) shape of parabolic surfaces P_{±}′ or facets 24 are formed with approximately linear Fresnel surfaces, based on a tangent to the corresponding parabolic surface. Typically, the Fresnel surfaces are also rotated to account for the translation along the y axis, in order to orient focuses F₊ and F₋ toward PV elements 14 on different opposing Fresnel reflectors 12.

Left and right-hand PV elements 14 are thus located at the focuses of right and left-hand Fresnel surfaces 16, respectively, increasing the available flux for conversion to electrical power. To reduce PV temperatures and increase efficiency, panel mounts 18 provide a direct heat conducting (or thermally conductive) coupling between PV elements 14 and minor backers 20, allowing excess heat to dissipate in the form of infrared emission from radiating surfaces 22.

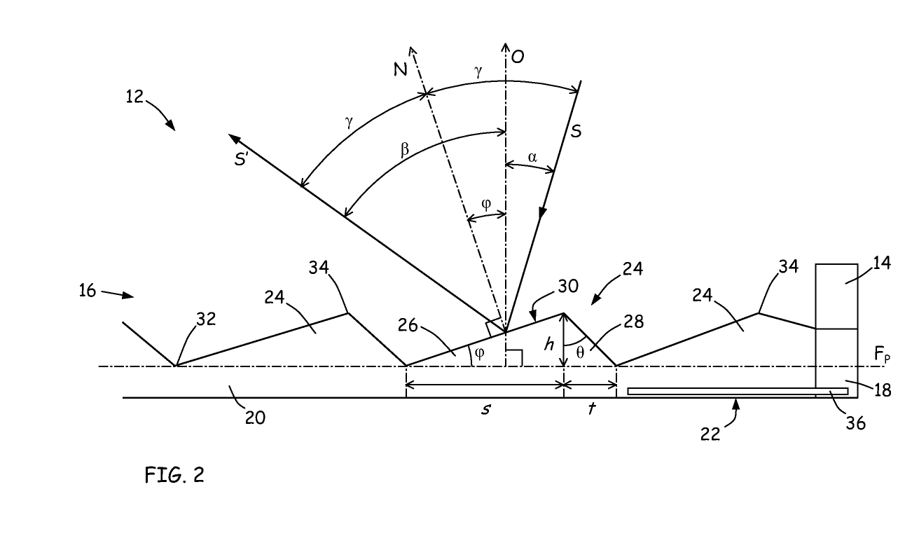

FIG. 2 is an illustration of facet geometry for Fresnel reflector 12 with panel-mounted PV element 14 and Fresnel surface 16. Fresnel surface 16 is formed on the front (first or top side) of minor backer 20, with radiating surface 22 on the back (second or bottom side), opposite Fresnel surface 16. PV element 14 is directly mounted to Fresnel reflector 12 via panel mount 18, providing heat dissipation via direct thermal contact with minor backer 20 and radiating surface 22.

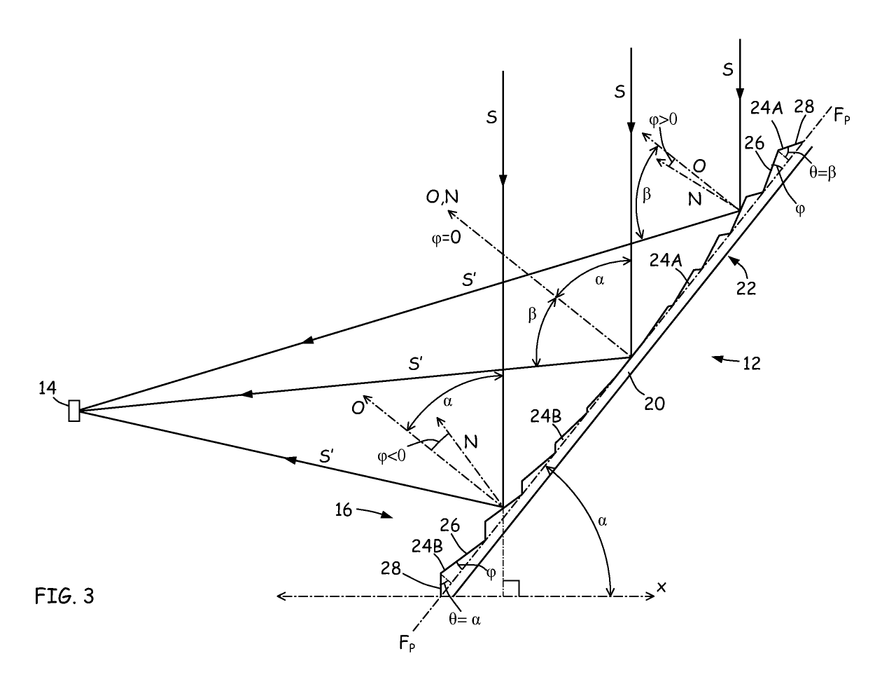

Fresnel surface 16 is formed as a number of individual Fresnel facets 24, each comprising front (or front-cut) facet section 26 and back-cut section (or cutback) 28. Each front section 26 is angled to focus light from source direction S onto a PV element (or other target) located at the focus Fresnel reflector 12, for example utilizing a linear-parabolic focusing geometry as described in more detail with respect to FIG. 3, below.

Facets 24 are formed by molding or cutting the front of minor backer 20, or by mechanical attachment thereto. A reflective material such as aluminum or silver is applied to form reflecting surface 30 of front facet section 26. In some embodiments, the reflective coating is also applied to cutback 28. In additional embodiments, one or more protective coatings are also applied in order to reduce oxidation, abrasion or adhesion, or to modify the optical properties of Fresnel surface 16.

Individual Fresnel facets 24 are characterized by facet height h, front-cut length s and cutback length t. Facet angle φ is formed by front section 26, and is measured with respect to Fresnel reflector 12 as defined along Fresnel plane F_{P}, as defined between adjacent inflection points 32. Inflection points 32 are located between individual facets 24, alternating with cusp points (peaks) 34.

In terms of height h and front-cut length s, facet angle φ is given by:

$$tan ϕ = \frac{h}{s} . \qquad [ 2 ]$$

Back-cut (or cutback) angle θ is measured from orthogonal vector O, perpendicular to Fresnel plane F_{P}, and is given by:

$$tan θ = \frac{t}{h} . \qquad [ 3 ]$$

The reflection geometry is defined in terms of normal vector N, perpendicular to reflecting surface 30 of front facet section 26. Normal vector N forms facet angle φ with respect to orthogonal vector O, and orthogonal vector O forms source angle α with respect to source direction S. The angle of incidence (γ) is measured from source direction S to normal vector N, and is equal to the sum of source angle α and facet angle φ:

γ=α+φ. [4]

In solar power applications the source distance is large and direction S is essentially constant over Fresnel surface 16, within the angular width of the sun. In terrestrial and low-earth-orbit applications, for example, the source distance is on the order of 150 million kilometers and the source width is about half a degree (½°), or plus-or-minus one quarter degree (±¼°). In deep space deployments and non-solar applications, the source distance and angular width vary.

For substantially planar constructions, orthogonal vector O is fixed with respect to Fresnel plane F_{P}, and source angle α is approximately constant over each section of Fresnel reflector 12, and across Fresnel surface 16. In curved (nonlinear) configurations, orthogonal vector O and source angle α are locally defined with respect to each individual facet 24.

Front facet sections 26 are individually oriented to reflect light from source direction S toward the focus, so Facet angle φ and normal vector N are different for each facet 24. Reflected (outgoing) light is directed along focus direction S′, making target angle β with respect to orthogonal vector O. The angle of incidence (γ) is equal to the angle of reflection, as measured about normal vector N, so target angle β is:

β=φ+γ. [5]

Combining with Eq. 5, above, facet angle φ is defined in terms of source angle α, from orthogonal vector O to source (incoming ray) direction S, and target angle β, from orthogonal vector O to focus (reflected ray) direction S′:

$$ϕ = \frac{β - α}{2} . \qquad [ 6 ]$$

Note that target angle β and source angle α are each measured from orthogonal vector O, but facet angle φ is defined as a difference so it does not matter what the reference is, as long as the same reference is used for both angles.

Light collection efficiency E of Fresnel reflector 12 depends on the fractional area of Fresnel surface 16 that is available to focus light. The fractional area is determined by facet geometry, and in particular by length s of front facet section 26 as compared to total length s+t of front section 26 and cutback 28:

$$E = \frac{s}{s + t} . \qquad [ 7 ]$$

In terms of facet angle φ and cutback angle θ, the collection efficiency is:

$$E = \frac{1}{1 + tan ϕtan θ} . \qquad [ 8 ]$$

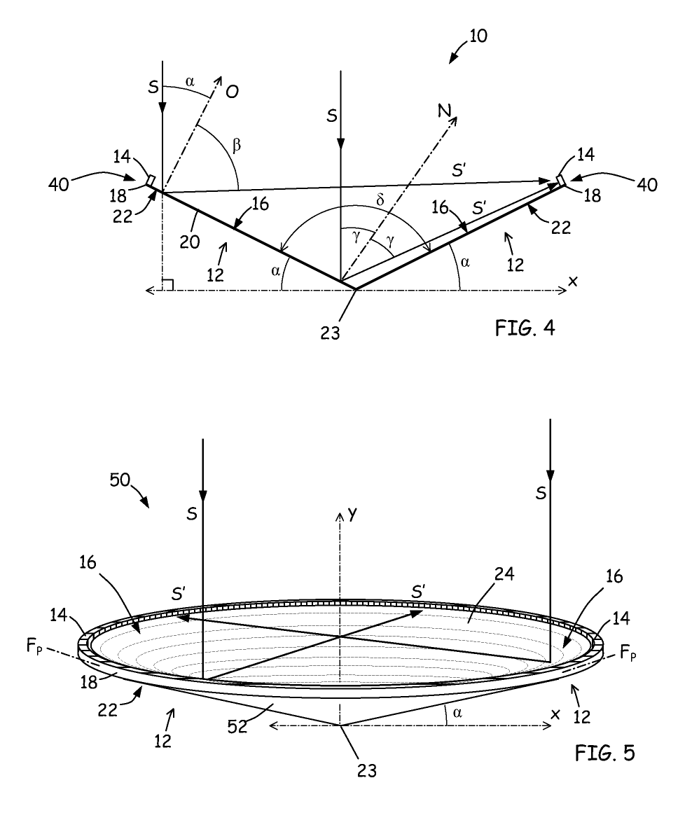

Collection efficiency E is relevant to the orientation of individual Fresnel reflectors 12, and in particular relates to the dihedral angle as described in more detail with respect to FIG. 4, below.

The structure of mirror backer 20 varies from embodiment to embodiment. In ground-based applications, suitable materials include wood, metals such as aluminum and steel, and combinations thereof. In these embodiments, Fresnel reflectors 12 are designed to withstand temperature excursions, rain, snow, ice and other adverse weather conditions, and other terrestrial environmental effects. In space-based applications, suitable materials include lightweight plastics and other polymers, composite carbon and glass-fiber materials, aluminum and titanium alloys, and combinations thereof. In these embodiments, Fresnel reflectors 12 are typically designed as lightweight structures that fold or stack for transportation, and are then deployed in a space environment.

Radiating surface 22 is formed on the back (second side) of minor backer 20, opposite Fresnel surface 16. In some embodiments, radiating surface 22 is uncoated, and in other embodiments radiating surface 22 is formed by applying one or more radiative or protective coatings, for example a polymer, paint-based or carbon-based coating, or a combination thereof.

Heat is conducted from PV element 14 to mirror backer 20 via panel mount 18. Panel mount 18 provides a direct, thermally conducting coupling between PV element 14 and minor backer 20, reducing the operating temperature of PV element 14 by transporting thermal energy to radiating surface 22, where it is dissipated by infrared emission.

In some embodiments, one or more cooling channels 36 are provided in minor backer 20 to increase thermal flow from PV element 14 by circulation of a cooling fluid. In particular, cooling channels 36 increase heat transfer from the region of minor backer 20 proximate panel mount 18, and distribute the heat over a larger region of radiating surface 22 to improve thermal dissipation and reduce the operating temperature of PV elements 14.

Heat also dissipates directly from PV element 14 and the structure of panel mount 18, but these elements tend to have relatively smaller surface areas as compared to minor backer 20, and thus emit less IR radiation. Additional heat also dissipates from Fresnel surface 16.

In general, the irradiance (or rate of heat dissipation per unit area, j) depends upon the fourth power of the local surface temperature, T, the emissivity of the surface, ε, and the Stefan-Boltzman constant, σ:

j=εσT⁴. [9]

Surface temperature T depends upon the temperature of PV element 14, the thermal conductivity of panel mount 18, and the distribution of heat over mirror backer 20. Emissivity ε depends upon the materials used to form Fresnel surface 16 and radiating surface 22.

In the visible spectrum, darker, optically absorptive materials tend to have higher emissivity (approaching one), and lighter, optically reflecting materials tend to have lower emissivity (approaching zero). In the infrared range, which is more relevant to the dissipation of heat energy, emissivity is less obviously correlated with visual color and appearance. For IR wavelengths of about 1 μm to about 14 μm, for example, the emissivity of rubber, plastics and most paints is relatively high, from about 0.90 to about 0.95, regardless of optical color. Carbon black, graphite and other carbon-based coatings, which are optically dark, have emissivity values of about 0.70 to about 0.90 in the IR. Reflective metals tend to have substantially lower IR emissivity, for example about 0.2 to about 0.4 for aluminum (0.10 or less for polished aluminum surfaces), and about 0.02 or less for silver.

As a result, for a given temperature T thermal dissipation tends to be greater from radiating surface 22 of minor backer 20 than from Fresnel surface 16. Coating cutbacks 28 does provide some thermal advantages, but the coating materials should be selected for a combination of IR emissivity and optical reflectivity in order to reduce direct heating. Regardless, the capacity to dissipate heat from PV element 14 depends primarily on the thermal coupling between PV element 14 and mirror backer 20, and in particular on the thermal coupling between panel mount 18 and radiating surface 22.

Direct panel mount 18 contrasts with other designs in which a PV element is positioned at a central focus located above Fresnel surface 16 (or other reflecting surface, such as a parabolic minor). In particular, PV element 14 is mounted in direct contact with Fresnel reflector 12, and the distance from PV element 14 to Fresnel surface 16 is typically less than a fraction of the focal length (e.g., less than 1/10 of the focal length). In suspended target designs, on the other hand, the PV-reflector spacing is approximately equal to the focal length, or at least an appreciable fraction thereof (e.g., more than ⅓ of the focal length).

In addition, the thermal coupling between PV element 14 and radiating surface 22 is a direct conductive coupling, rather than an indirect coupling. Other designs rely on convective airflow (e.g., in terrestrial solar concentrator systems) or additional cooling systems (e.g. radiating fins or cooling fluid loops) to transport heat away PV elements 14, rather than a direct thermally conducting panel mount between PV elements 14 and Fresnel reflector 12, as described herein.

FIG. 3 is an illustration of focusing geometry for Fresnel reflector 12, in a linear-parabolic embodiment. Fresnel surface 16 of reflector 12 comprises a plurality of facets 24 formed on a first surface (front side) of minor backer 20, with radiating surface 22 on the second (back) side. Each facet 24 is oriented to direct light from source direction S toward PV element 14, located approximately at the focal point of Fresnel surface 16.

As shown in FIG. 3, Fresnel reflectors 12 are oriented at angle α with respect to the x axis, where the x axis is perpendicular to source direction S, the propagation direction of incoming rays (incident light). Orthogonal vector O is perpendicular to Fresnel reflector 12 along Fresnel plane F_{P}, and oriented at angle α with respect to source direction S. Normal vector N is perpendicular to the Fresnel surface of facet 24, and oriented at angle β with respect to focus direction S′.

Facets 24 are divided into two different sets or orientations, depending upon on whether facet angle φ is positive, negative or zero. Based on Eq. 6, above, φ>0 when target angle β is greater than source angle α, giving facets 24A a first or forward orientation, as shown in the top right portion of FIG. 3. For forward-facing (ff) facets 24A, front section 26 is positioned toward the focus (along focus direction S′), to the left and below cutback 28. Cutback 28 is positioned away from the focus, above and to the right of front section 26. In order to reduce shadowing and increase the effective area of Fresnel surface 16, cutback angle θ is selected to orient the surface of cutback 28 along focus direction S′; that is, approximately equal to target angle β:

θ_{ff}=β. [10]

When target angle β is less than source angle α, facet angle φ is less than zero and facets 24B have a reverse orientation, as shown in the bottom left of FIG. 3. For reverse facing (rf) facets 24B, cutback 28 is oriented toward the focus (along focus direction S′), with front section 26 positioned above and to the right of cutback 28. Cutback angle θ is selected to orient the surface of cutback 28 along source direction S, approximately equal to source angle α:

θ_{rf}=α. [11]

When target angle β is equal to source angle α, facet angle φ is approximately zero and the Fresnel surface is formed along (or parallel to) Fresnel reflector 12, as defined along Fresnel plane F_{P}. In this configuration the facet height is essentially zero, and there is no substantial distinction between front-cut section 26 and cutback section 28.

Note that facet angle φ is sometimes defined in an opposite sense, or as a non-negative or positive-definite number. Facet orientation can also be interpreted in terms of a reversal of source (incident ray) direction S and focus (reflected ray) direction S′, or as a reversal of source angle α and target angle β. Under any of these conventions, first and second facet orientations are still distinguishable based on whether cutback angle θ lies along the reflected ray with focus direction S′ (forward-facing facets 24A) or along the incident ray with source direction S (reversed facets 24B). Similarly, the set of forward-facing facets 24A has normal vector N oriented toward the reflected ray (toward focus direction S′) with respect to orthogonal vector O, and the set of reversed facets 24B have normal vector N oriented away from the reflected ray (toward source direction S) with respect to orthogonal vector O.

FIG. 4 is a cross-sectional schematic diagram of concentrating photovoltaic power system 10. In this particular embodiment, CPV system 10 comprises two Fresnel reflectors 12 joined in a “V” configuration with dihedral angle δ at vertex 23. Fresnel surfaces 16 are presented on the top (front) of Fresnel reflector 12, opposite radiating surface 22 on the bottom (back). PV elements 14 are directly mounted to Fresnel reflectors 12 at panel mounts 18, in an edge-mounted configuration with panel mounts 18 positioned at outer edges 40, opposite vertex 23.

As shown in FIG. 4, Fresnel reflectors 12 are symmetrically oriented at angle α with respect the x axis, which is perpendicular to source (incident ray) direction S. The orientation of Fresnel reflectors 12 also defines source angle α with respect to orthogonal vector O, where orthogonal vector O is perpendicular to Fresnel reflector 12. Target angle β is defined with respect to target (reflected ray) direction S′, and dihedral angle δ is determined by source angle α:

δ=π−2α. [12]

The collection efficiency of Fresnel reflector 12 depends upon facet angle φ and cutback angle θ, which in term depend upon the facet position along the Fresnel plane, and the corresponding facet orientation with respect to focus direction S′. Facets 24 near top or outer edge 40 of Fresnel reflector 12, opposite vertex 23, are typically forward-facing (φ>0) with cutback angle θ approximately equal to target angle β. In this configuration the cutback is oriented along the reflected ray and toward the focus, and the collection efficiency (Eq. 8) is:

$${E}_{ff} = \frac{1}{1 + tan ϕtanβ} . \qquad [ 13 ]$$

In general, facet angle φ is half the difference between target angle β and source angle α (Eq. 6), and, based on FIG. 4, near outer edge 40 of Fresnel reflector 12 target angle β is approximately the complement of source angle α:

$$β \approx \frac{π}{2} - α . \qquad [ 14 ]$$

Based on Eqs. 13 and 14, the highest-efficiency dihedral angle for facets near the outer edge of Fresnel reflector 12 is about 90°, or δ≈π/2.

Facets at the bottom of Fresnel reflectors 12 (near vertex 23) are typically reversed (that is, φ<0), with cutback angle θ approximately equal to source angle α. This orients the cutback along source (incoming ray) direction S, and with efficiency:

$${E}_{rf} = \frac{1}{1 + tan ϕtan α} . \qquad [ 15 ]$$

Near vertex 23, the angle of incidence/angle of reflection (γ) is given by

$$2 γ \approx \frac{π}{2} - α . \qquad [ 16 ]$$

Based on Eqs. 4 and 5 (with related discussion of FIG. 2, above), this gives:

$$γ \approx \frac{α + β}{2} . \qquad [ 17 ]$$

In this configuration the relationship between target angle β and source angle α is:

$$β \approx \frac{π}{2} - 2 α , \qquad [ 18 ]$$

and the highest-efficiency dihedral angle for facets near vertex 23 is about 120°, or δ≈2π/3.

In typical embodiments, therefore, the optimal dihedral angle for a V-shaped two-panel linear-parabolic system is between about 90° and about 120°, depending on whether the facets are located near vertex 23 or outer edge 40. Averaged over the surface of Fresnel reflectors 12, the optimal dihedral angle is between about 100° and about 110°. In some embodiments the optimal dihedral angle is approximately the geometric mean of about 105°, or between about 104° and about 106°. Alternatively, the optical dihedral angle is about 104°, based on a numerical computation performed along the full width of Fresnel reflector 12.

FIG. 5 is a perspective view of conic dish CPV system 50. In this particular embodiment, Fresnel reflectors 12 form a continuous body of rotation about source direction S, formed essentially by rotating Fresnel surfaces 16 about vertical axis y at vertex 23, forming a V-shaped conic dish concentrator 52.

Fresnel surfaces 16 are formed on the front surface (top) of mirror backer 20, with radiating surfaces 22 on the back (bottom), opposite Fresnel surfaces 16. Individual sections of Fresnel reflector 12 are oriented at angle α with respect to horizontal reference axis x, forming dihedral angle δ=π−2α as described above. Facets 24 are angled to focus light incident on Fresnel surfaces 16 from source direction S toward PV elements 14.

PV elements 14 are arranged in a circular arrangement along the top edge of conic-dish concentrator 52, within the annular focus regions of Fresnel surfaces 16, and attached to the rim of dish concentrator 52 via panel mounts 18. Panel mounts 18 provide a direct thermal pathway for conducting heat energy away from PV elements 14 to mirror backer 20, and for dissipating the heat via IR emission from radiating surfaces 22.

In the particular embodiment of FIG. 5, individual facets 24 are substantially continuous and annular in form, and there are an arbitrary number of Fresnel planes F_{P}, each defining a separate section of Fresnel reflectors 12. In other embodiments, conic concentrator 52 is formed as a number of discrete triangular Fresnel reflectors 12, with Fresnel surfaces 16 and facets 24 divided into a corresponding number of discrete sections.

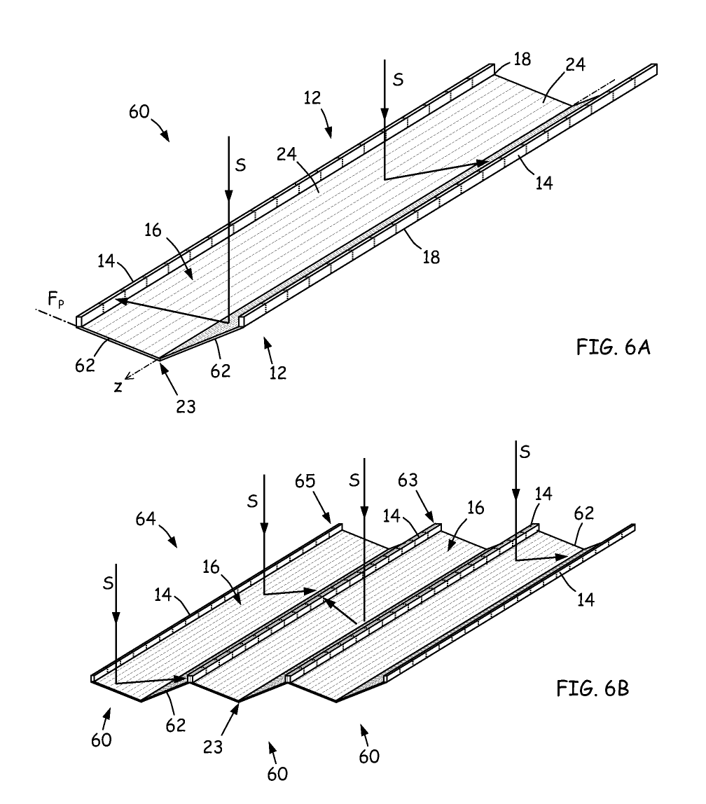

FIG. 6A is a perspective view of two-panel linear-parabolic CPV system 60. In this embodiment individual concentrator panels 62 are formed by extending linear-parabolic Fresnel reflectors 12 along axis z, perpendicular to source direction S along Fresnel surfaces 16. Concentrator panels 62 are formed as substantially rectilinear structures, and joined at vertex 23 using a folding hinge or other joint structure as described above.

Individual facets 24 are substantially rectangular or linear in form, and angled to focus incident light from source direction S onto PV elements 14 along outer the outer edges of concentrator panels 62, opposite vertex 23. In this particular embodiment, PV elements 14 comprise rows of individual photovoltaic devices arranged along the top (unjoined) edges of each concentrator panel 62, and attached to Fresnel surface 16 via panel mounts 18, utilizing two-directional linear parabolic focusing to focus light from source direction S onto both rows of PV elements 14.

FIG. 6B is a perspective view of CPV array 64, formed of two or more two-panel linear-parabolic CPV systems 60. Individual concentrator panels 62 are joined at the outer edges along (interior) apexes 63, alternating with vertexes 23. In typical embodiments, PV elements 14 are mounted in two rows mounted along each interior apex 63, oriented to capture light from linear-parabolic Fresnel surfaces 16 on the left and right side, respectively. Only one row of PV elements 14 is provided along exterior edges 65, oriented toward the corresponding (interior) Fresnel surface 16.

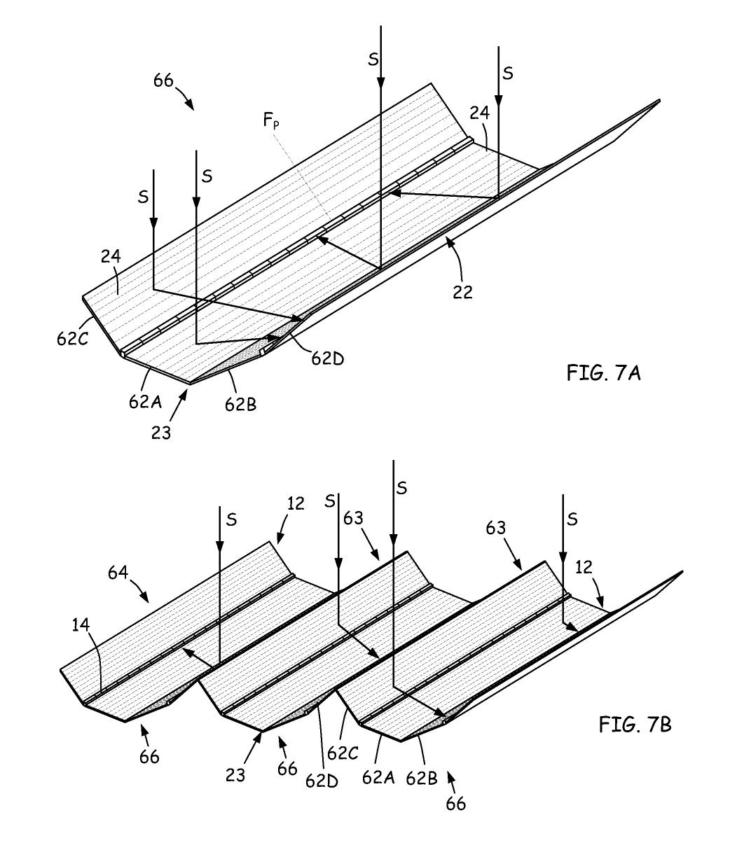

FIG. 7A is a perspective view of four-panel bilinear parabolic CPV system 66. In this embodiment, first and second concentrator panels 62A and 62B are joined at central vertex 23, with third concentrator panel 62C joined to the left edge of first panel 62A and fourth concentrator panel 62D joined to the right edge of second panel 62B. PV elements 14 are configured in two rows. The first row of PV elements 14 is located between first and third concentrator panels 62A and 62C, along the focus of Fresnel surfaces 16 on second and fourth concentrator panels 62B and 62D. The second row of PV elements 14 is located between second and fourth concentrator panels 62B and 62D, along the focus of Fresnel surfaces 16 on first and third concentrator panels 62A and 62C. Middle (interior) vertex 23 between concentrator panels 62A and 62B is not instrumented.

Four-panel CPV system 66 utilizes a bilinear parabolic focusing arrangement in which Fresnel surfaces 16 on the first and third (left hand) concentrator panels 62A and 62C focus light onto the right-hand row of PV elements 14, between second and fourth concentrator panels 62B and 62D, and Fresnel surfaces 16 on second and fourth (right-hand) concentrator panels 62B and 62D focus light onto the left-hand row of PV elements 14, between first and third concentrator panels 62A and 62C. Because PV elements 14 are mounted between joined concentrator panels, rather than on an unjoined (exposed) edge, heat is conducted across a larger area of radiating surfaces 22, increasing thermal transfer and reducing the operating temperature of PV elements 14.

In this particular embodiment, individual Fresnel facets 24 also have variable width in order to improve focusing onto PV elements 14. In particular, due to the angular width of the source, light reflected from facets 24 spreads out with focal distance D (the distance from the facet to the focus), resulting in larger focusing area for facets 24 with larger reflected pathlengths to PV elements 14. In linear-parabolic embodiments, for example, this increases the width of the rectangular focus so that the reflected beam extends above and below PV elements 14. For a conic dish, the focus is an annulus but the effect is substantially similar.

To account for beam spreading and conform the focal area to the corresponding sensitive region of PV elements 14, facets 24 are sometimes defined with a variable dimension such as width W_{F}, as defined along Fresnel plane F_{P}, based on the corresponding desired width W_{PV} of the reflected beam at PV element 14. For linear beam spreading, the Fresnel width is

W_{F}=W_{PV}−AD. [19]

In solar power embodiments, A=½°, the full angular width of the sun.

FIG. 7B is a perspective view of CPV array 64, in an embodiment formed of two or more four-panel bilinear systems 66. Individual concentrator panels 62D and 62C are joined at interior apexes 63, alternating with interior vertexes 23. In contrast to two-panel array 64 of FIG. 6B, above, interior apexes 63 are not instrumented because the four-panel bilinear focusing arrangement of CPV systems 66 directs light onto only one side of each row of PV elements 14, and does not require two rows of PV elements 14 with different orientations.

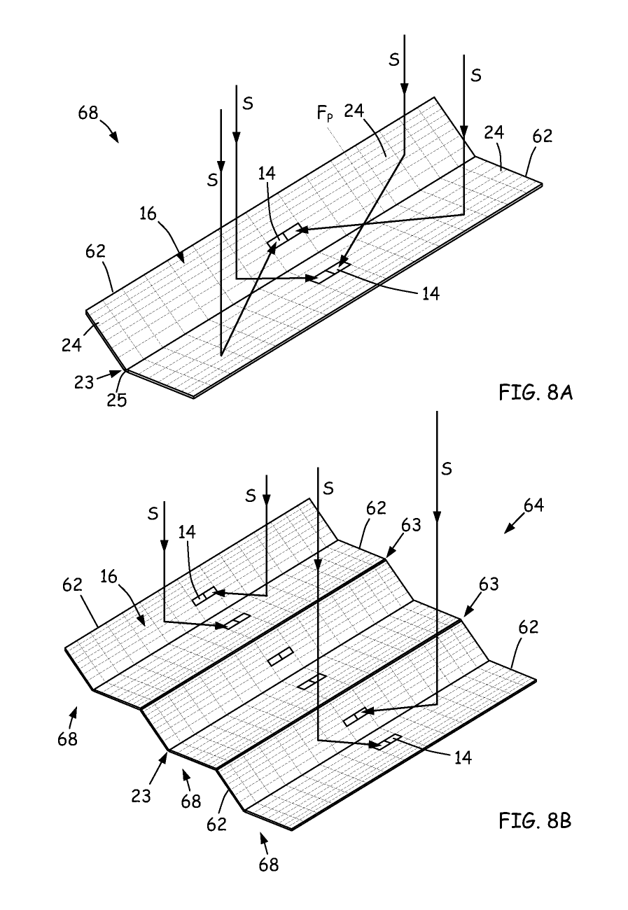

FIG. 8A is a perspective view of CPV system 68 with two-dimensional focusing. First and second concentrator panels 62 are joined at vertex 23, for example at hinge mechanism 25 as described above. In this embodiment, however, facets 24 are angled in two independent directions, in order to provide two-dimensional focusing toward the focal area of PV elements 14.

Two-dimensional focusing provides greater solar concentration onto PV elements 14, and greater flexibility in PV placement. In particular, the length of the focal area (and the corresponding linear extent of PV elements 14) is substantially less than that of the Fresnel plane itself. Thus PV elements 14 need not span the full length of concentrator panels 62, but are instead mounted within the field of Fresnel reflector 12, with particular location corresponding to the (smaller) focus region of the corresponding Fresnel surface 16.

FIG. 8A also shows a more general placement of PV elements 14 within the field of Fresnel surface 16, where PV elements 14 are spaced from the outer edges of concentrator panels 62 and spaced from vertex 23. This design flexibility is characteristic of both one- and two-dimensional focusing arrangements, although for one-dimensional focusing the row of PV elements 14 typically extends along the length of each concentrator panel 62, regardless of whether the row is mounted along an edge or at an interior field location.

In two-dimensional focusing embodiments, the dimensions of individual facets 24 are thus variable both length and width, in order to provide better focusing in both dimensions. Specifically, length L_{F} of each facet 24 is defined along Fresnel plane F_{P} in a direction transverse to the width, and length L_{F} is varied based on beam spread angle A and focal distance D in order to reduce length L_{PV} of the focal region to correspond to the sensitive area of PV elements 14:

L_{F}=L_{PV}−AD. [20]

FIG. 8B is a perspective view of CPV array 64, formed of two or more two-dimensional focusing CPV systems 68. In this particular embodiment, individual concentrator panels 62 are joined along interior apexes 63, as described above for arrays with outer edge-mounted PV elements 14, but in this embodiment neither apexes 63 nor vertexes 23 are instrumented because PV elements 14 are mounted to within the interior field of Fresnel surface 16.

While the invention has been described with reference to exemplary embodiments, it will be understood by those skilled in the art that various changes may be made and equivalents may be substituted without departing from the spirit and scope of the invention, and modifications may be made to adapt particular situations or materials to the teachings of the invention without departing from the essential scope thereof. The invention is thus not limited to the particular embodiments disclosed herein, but includes all embodiments falling within the scope of the appended claims.

1. A system comprising:
first and second Fresnel reflectors, each of the Fresnel reflectors comprising:
a Fresnel surface having a focus;
a radiating surface opposite the Fresnel surface; and
a photovoltaic element mounted to the Fresnel surface, in thermally conducting contact with the radiating surface;
wherein the first and second Fresnel reflectors form a vertex at a dihedral angle, such that the focus of the first Fresnel reflector is directed toward the photovoltaic element on the second Fresnel reflector, and such that the focus of the second Fresnel reflector is directed toward the photovoltaic element on the first Fresnel reflector.

2. The system of claim 1, wherein the photovoltaic element comprises a row of photovoltaic devices mounted to the Fresnel surface along an outer edge of the Fresnel reflector, opposite the vertex.

3. The system of claim 2, wherein the dihedral angle is between about 100 degrees and about 110 degrees.

4. The system of claim 3, wherein the dihedral angle is between about 104 degrees and about 106 degrees.

5. The system of claim 1, wherein the photovoltaic element comprises a photovoltaic device mounted within a field of the Fresnel surface, spaced from an outer edge of the Fresnel reflector and spaced from the vertex.

6. The system of claim 1, wherein the Fresnel surface comprises facets angled to reflect light from a source toward the focus.

7. The system of claim 6, wherein the first and second Fresnel reflectors comprise first and second sections of a conic dish, and wherein the facets have substantially annular form.

8. The system of claim 6, wherein the first and second Fresnel reflectors form substantially planar panel structures, and wherein the facets have substantially rectangular form.

9. The system of claim 6, wherein a first set of the facets have cutbacks aligned toward the source and a second set of the facets have cutbacks aligned toward the focus.

10. The system of claim 1, wherein the facets have variable widths based on distance to the focus and beam spreading, such that focal areas of the Fresnel surfaces substantially conform to sensitive areas of the photovoltaic elements.

11. The system of claim 1, wherein the facets are angled in two independent directions to provide two-dimensional focusing onto a photovoltaic device.

12. The system of claim 1, further comprising a third Fresnel reflector coupled to the first Fresnel reflector such that a focus of the third Fresnel reflector is directed toward the photovoltaic element on the second Fresnel reflector.

13. The system of claim 12, further comprising a fourth Fresnel reflector coupled to the second Fresnel reflector such that a focus of the fourth Fresnel reflector is directed toward the photovoltaic element on the first Fresnel reflector.

14. A solar concentrator comprising:
first and second Fresnel reflectors, each of the Fresnel reflectors comprising:
a Fresnel surface comprising facets having a facet angle oriented to reflect light from a source direction toward a focus;
a radiating surface opposite the Fresnel surface; and
a photovoltaic device mounted to the Fresnel surface, in thermally conducting contact with the radiating surface;
wherein the first and second Fresnel reflectors form a vertex having a dihedral angle, such that the focus of the first Fresnel reflector is directed toward the photovoltaic device on the second Fresnel reflector, and such that the focus of the second Fresnel reflector is directed toward the photovoltaic device on the first Fresnel reflector.

15. The solar concentrator of claim 14, wherein a first set of the facets have cutback angles oriented along the source direction and a second set of the facets have cutback angles oriented toward the focus.

16. The solar concentrator of claim 15, wherein the photovoltaic device is mounted to an outer edge of the Fresnel reflector and wherein the dihedral angle is between about 100 degrees and about 110 degrees.

17. The solar concentrator of claim 14, wherein the photovoltaic device is mounted within a field of the Fresnel surface, spaced from an outer edge of the Fresnel reflector and spaced from the vertex.

18. The solar concentrator of claim 14, wherein the facets have variable widths along the Fresnel surface to account for beam spreading based on distance to the focus.

19. The solar concentrator of claim 14, wherein the facets are angled in two independent directions to provide two-dimensional focusing, such that a length of a focal area of the Fresnel surface is less than a length of the Fresnel reflector.

20. A concentrating photovoltaic system comprising:
a plurality of Fresnel reflectors, each of the Fresnel reflectors comprising:
a Fresnel surface comprising facets oriented to reflect light from a source direction toward a focus direction, wherein a first set of the facets have cutbacks oriented along the source direction and a second set of the facets have cutbacks oriented along the focus direction;
a radiating surface opposite the Fresnel surface; and
a photovoltaic element mounted to the Fresnel surface, in thermally conducting contact with the radiating surface;
wherein two of the plurality of Fresnel reflectors are coupled to form a vertex having a dihedral angle, and wherein each of the Fresnel reflectors is positioned such that the focus direction is oriented toward a photovoltaic element on a different Fresnel reflector.

21. The concentrating photovoltaic system of claim 20, wherein the photovoltaic element is mounted to the Fresnel surface at an outer edge of the Fresnel reflector, and wherein the dihedral angle is between about 100 degrees and about 110 degrees.

22. The concentrating photovoltaic system of claim 21, wherein the dihedral angle is between about 104 degrees and about 106 degrees.

23. The concentrating photovoltaic system of claim 20, wherein the photovoltaic element is mounted within a field of the Fresnel surface, spaced from an outer edge of the Fresnel reflector and spaced from the vertex.

24. The concentrating photovoltaic system of claim 23, wherein the facets are angled in two independent directions to provide two-dimensional focusing toward the photovoltaic element on the different Fresnel reflector.

25. The concentrating photovoltaic system of claim 20, wherein the facets have variable lengths and widths along the Fresnel surface to account for beam spreading.
